(19) United States
(12) Patent Application Publication
(10) Pub. No.: US 2012/0001164 A1
(43) Pub. Date: Jan. 5, 2012

(54) ORGANIC ELECTRONIC DEVICE WITH ELECTRON TUNNELING LAYER

(75) Inventors: Weiying Gao, Landenberg, PA (US); Dean T. Deibler, Boothwyn, PA (US)

(73) Assignee: E.I. DU PONT DE NEMOURS AND COMPANY, Wilmington, DE (US)

(21) Appl. No.: 13/256,289

(22) PCT Filed: May 11, 2010
(86) PCT No.: PCT/US10/34341

§ 371 Date: Sep. 13, 2011

Related U.S. Application Data
(60) Provisional application No. 61/177,308, filed on May 12, 2009.

(51) Int. Cl. H01L 51/52; H01L 51/54

(52) U.S. Cl. 257/40; 257/E51.024; 257/E51.018

(57) ABSTRACT

There is provided an organic electronic device including an anode; a photoactive layer; an electron transport layer; an electron tunneling layer having a thickness in the range of 10-50 Å; and a cathode.

### RELATED APPLICATION

This application claims priority under 35 U.S.C. §119(e) from Provisional Application No. 61/177,308 filed May 12, 2009 which is incorporated by reference in its entirety.

### BACKGROUND INFORMATION

1. Field of the Disclosure

This disclosure relates in general to organic electronic devices and particularly to device architecture including an electron tunneling layer.

2. Description of the Related Art

In organic electronic devices, such as organic light emitting diodes (“OLED”), that make up OLED displays, the organic active layer is sandwiched between two electrical contact layers. In an OLED, at least one of the electrical contact layers is light-transmitting, and the organic active layer emits light through the light-transmitting electrical contact layer upon application of a voltage across the electrical contact layers.

It is well known to use organic electroluminescent compounds as the active component in light-emitting diodes. Simple organic molecules, conjugated polymers, and organometallic complexes have been used. Devices frequently include one or more charge transport layers, which are positioned between a photoactive (e.g., light-emitting) layer and an electrical contact layer. A device can contain two or more contact layers. A hole transport layer can be positioned between the photoactive layer and the hole-injecting contact layer. The hole-injecting contact layer may also be called the anode. An electron transport layer can be positioned between the photoactive layer and the electron-injecting contact layer. The electron-injecting contact layer may also be called the cathode. Charge transport materials can also be used as hosts in combination with the photoactive materials.

There is a continuing need for devices with improved properties.

### SUMMARY

There is provided an organic electronic device comprising:
an anode;
a photoactive layer;
an electron transport layer;
an electron tunneling layer having a thickness in the range of 10-50 Å; and
a cathode.

In another embodiment, the device further comprises a hole injection layer and/or a hole transport layer between the anode and the photoactive layer.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of one example of an organic electronic device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms, followed by the Electronic Device and Examples.

### 1. Definitions and Clarification of Terms

Before addressing details of embodiments described below, some terms are defined or clarified.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the terms “charge transport layer, material, member, or structure,” “hole transport layer, material, member, or structure,” and “electron transport layer, material, member, or structure” are not intended to include a layer, material, member, or structure whose primary function is light emission or light absorption.

The term “dopant” is intended to mean a material, within a layer including a host material, that changes the wavelength(s) of radiation emission of the layer compared to the wavelength(s) of radiation emission in the absence of such material. A dopant of a given color refers to a dopant which emits light of that color.

The term “electron tunneling” is intended to refer to the pure quantum mechanical effect of electron transport through energy barriers. The electrons are treated as waves that can penetrate through materials that do not allow propagation. Electrons can tunnel through the barrier material if the barrier is sandwiched between two materials that allow electron propagation and if the barrier is thin enough, typically of the order of nanometers. The tunneling current is inversely and exponentially dependent on the barrier width.

The term “host material” is intended to mean a material, usually in the form of a layer, to which a dopant may or may not be added. The host material may or may not have electronic characteristic(s) or the ability to emit, receive, or filter radiation. When a dopant is present in a host material, the host material does not significantly change the emission wavelength of the dopant material.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

The term “liquid composition” is intended to mean a liquid medium in which a material is dissolved to form a solution, a liquid medium in which a material is dispersed to form a dispersion, or a liquid medium in which a material is suspended to form a suspension or an emulsion.

The term “liquid medium” is intended to mean a liquid material, including a pure liquid, a combination of liquids, a solution, a dispersion, a suspension, and an emulsion. Liquid medium is used regardless whether one or more solvents are present.

The term “photoactive” is intended to mean to any material that exhibits electroluminescence or photosensitivity.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited in case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Electronic Device

Organic electronic devices that may benefit from having one or more layers comprising the green luminescent materials described herein include, but are not limited to, (1) devices that convert electrical energy into radiation (e.g., a light-emitting diode, light emitting diode display, or diode laser), (2) devices that detect signals through electronics processes (e.g., photodetectors, photoconductive cells, photoresistors, photoswitches, phototransistors, phototubes, IR detectors, biosensors), (3) devices that convert radiation into electrical energy, (e.g., a photovoltaic device or solar cell), and (4) devices that include one or more electronic components that include one or more organic semi-conductor layers (e.g., a transistor or diode).

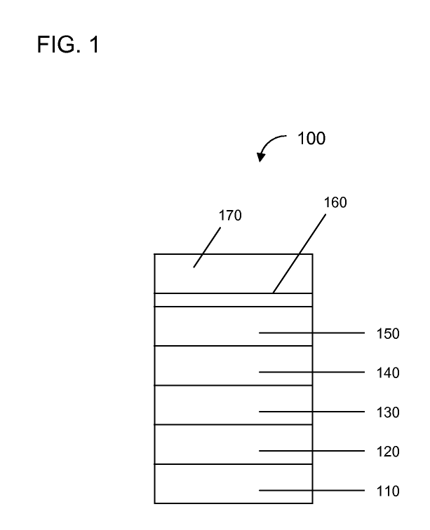

One illustration of an organic electronic device structure is shown in FIG. 1. The device 100 has a first electrical contact layer, an anode layer 110, a photoactive layer 140, an electron transport layer 150, an electron tunneling layer 160 and a second electrical contact layer, a cathode layer 170. Adjacent to the anode is an optional hole injection layer 120. Adjacent to the hole injection layer is an optional hole transport layer 130, comprising hole transport material. Additional layers may optionally be present. As an option, devices may use one or more additional hole injection or hole transport layers (not shown) next to the anode 110 and/or one or more additional electron transport layers (not shown) between the photoactive layer and the electron barrier layer. The layers between the anode 110 and the cathode 170 are individually and collectively referred to as the active layers.

In organic light emitting diodes (“OLEDs”) the photoactive layer is an emissive layer. OLEDs work by having electrons and holes injected into the emissive layer, where electrons and holes recombine and generate light. Balancing electrons and holes is an important factor for achieving high efficiency. Materials having high electron mobility, such as phenanthrolines, are often used as the electron transport layer to obtain high power efficiency. However, in these devices the lifetime often is adversely affected. Organic materials, in general, are known to be relatively unstable with respect to electrons. Several different approaches have been used to control the electron current in OLEDs. In one approach, a material having low electron mobility or a shallow lowest unoccupied molecular orbital (“LUMO”) is inserted between the emissive layer (“EML”) and the electron transport layer (“ETL”) in order to reduce electron injection. In another approach, an electron trapping material is added into the EML, hole transport layer (“HTL”), or both to capture electrons and prevent them from getting deeper into the rest of the device. However, these methods add more complexity into the already demanding OLED manufacturing process. At the same time they create additional problems, such as exciton quenching by trapped electrons, or by the low electron mobility of the narrow gap material layer.

There is provided herein an organic electronic device comprising:
an anode;
a photoactive layer;
an electron transport layer;
an electron tunneling layer having a thickness in the range of 10-50 Å; and
a cathode.
   It has been found that the addition of an electron tunneling layer results in adjustable electron current. Unexpectedly and surprisingly, it has been found that device lifetime is improved at optimal thickness of the electron tunneling layer. The electron tunneling layer is between and in physical contact with the electron transport layer and the cathode, both of which allow electron propagation.

In some embodiments, the device further comprises a hole injection layer between the anode and the photoactive layer. In some embodiments, the device further comprises a hole transport layer between the anode and the photoactive layer. In some embodiments, the photoactive layer is an emissive layer.

In some embodiments, the organic electronic device comprises:
an anode;
a hole injection layer;
a hole transport layer;
an emissive layer;
an electron transport layer;
an electron tunneling layer having a thickness in the range of 10-50 Å; and
a cathode.

In some embodiments, the organic electronic device consists essentially of:
an anode;
a hole injection layer;
a hole transport layer;
an emissive layer;
an electron transport layer;
an electron tunneling layer having a thickness in the range of 10-50 Å; and
a cathode.
   a. Electron Tunneling Layer

The electron tunneling layer 160 has a thickness in the range of 10-50 Å. In some embodiments, the layer has a thickness in the range of 14-35 Å; in some embodiments, 20-30 Å.

In some embodiments, the electron tunneling layer comprises a material that is an oxide or fluoride of an alkali or alkaline earth metal. In some embodiments, the electron tunneling layer comprises a material selected from the group consisting of LiF, Li₂O, Li-containing organometallic compounds, Cs-containing organometallic compounds, CsF, Cs₂O, Cs₂CO₃ and combinations thereof. The organometallic compounds can be alkylmetal compounds or arylmetal compounds. Examples include, but are not limited to, phenyllithium, t-butyllithium, and methylcesium. In some embodiments, the electron tunneling layer consists essentially of a material selected from the group consisting of LiF, Li₂O, Li-containing organometallic compounds, Cs-containing organometallic compounds, CsF, Cs₂O, Cs₂CO₃ and combinations thereof. In some embodiments, the electron tunneling layer consists essentially of a material selected from the group consisting of LiF and CsF.

b. Other Device Layers

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also comprise an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The optional hole injection layer 120 comprises hole injection material. Hole injection materials are generally electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Hole injection materials may be polymers, oligomers, or small molecules, and may be in the form of solutions, dispersions, suspensions, emulsions, colloidal mixtures, or other compositions.

The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The hole injection layer can comprise charge transfer compounds, and the like, such as copper phthalocyanine and the tetrathiafulvalene-tetracyanoquinodimethane system (TTF-TCNQ). In one embodiment, the hole injection layer is made from a dispersion of a conducting polymer and a colloid-forming polymeric acid. Such materials have been described in, for example, published U.S. patent applications 2004-0102577, 2004-0127637, and 2005-205860.

The optional hole transport layer 130 comprises hole transport material. Examples of hole transport materials for the hole transport layer have been summarized for example, in Kirk-Othmer Encyclopedia of Chemical Technology, Fourth Edition, Vol. 18, p. 837-860, 1996, by Y. Wang. Both hole transporting small molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 4,4′-bis(carbazol-9-yl)biphenyl (CBP); 1,3-bis(carbazol-9-yl)benzene (mCP); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. Examples of crosslinkable hole transport polymers can be found in, for example, published US patent application 2005-0184287 and published PCT application WO 2005/052027. In some embodiments, the hole transport layer is doped with a p-dopant, such as tetrafluorotetracyanoquinodimethane and perylene-3,4,9,10-tetracarboxylic-3,4,9,10-dianhydride.

Depending upon the application of the device, the photoactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In some embodiment, the photoactive layer is an emissive layer and comprises organic electroluminescent (“EL”) material. Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. In some cases the small molecule fluorescent or organometallic materials are deposited as a dopant with a host material to improve processing and/or electronic properties. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The electron transport layer 150 comprises electron transport material. Examples of electron transport materials include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); triazines; fullerenes; and mixtures thereof. In some embodiments, the electron transport material is selected from the group consisting of metal quinolates and phenanthroline derivatives.

In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

The cathode 170 is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

It is known to have other layers in organic electronic devices. For example, there can be a layer (not shown) between the anode and hole injection layer to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of the anode layer, the cathode layer, and the active layers between these layers, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

In one embodiment, the different layers have the following range of thicknesses: anode, 500-5000 Å, in one embodiment 1000-2000 Å; optional hole injection layer, 50-2000 Å, in one embodiment 200-1000 Å; optional hole transport layer, 50-2000 Å, in one embodiment 200-1000 Å; photoactive layer, 10-2000 Å, in one embodiment 100-1000 Å; electron transport layer, 50-500 Å, in one embodiment 100-300 Å; electron tunneling layer 10-50 Å, in one embodiment 15-35 Å; cathode, 200-10000 Å, in one embodiment 300-5000 Å. The desired ratio of layer thicknesses will depend on the exact nature of the materials used.

The device layers can be formed by any deposition technique, or combinations of techniques, including vapor deposition, liquid deposition, and thermal transfer. Substrates such as glass, plastics, and metals can be used. Conventional vapor deposition techniques can be used, such as thermal evaporation, chemical vapor deposition, and the like. The organic layers can be applied from solutions or dispersions in suitable solvents, using conventional coating or printing techniques, including but not limited to spin-coating, dip-coating, roll-to-roll techniques, ink-jet printing, continuous nozzle printing, screen-printing, gravure printing and the like.

In some embodiments, the device is fabricated by liquid deposition of the hole injection layer, the hole transport layer, and the emissive layer, and by vapor deposition of the anode, the electron transport layer, the electron tunneling layer and the cathode.

In some embodiments, the device is fabricated by liquid deposition of the hole injection layer, and by vapor deposition of the anode, the hole transport layer, the emissive layer, the electron transport layer, the electron tunneling layer and the cathode.

In some embodiments, the device is fabricated by vapor deposition of the anode, the electron tunneling layer and the cathode, and by liquid deposition of all the other layers.

It is understood that the efficiency of devices made with the new compositions described herein, can be further improved by optimizing the other layers in the device. For example, more efficient cathodes such as Ca or Ba can be used. Shaped substrates and novel hole transport materials that result in a reduction in operating voltage or increase quantum efficiency are also applicable. Additional layers can also be added to tailor the energy levels of the various layers and facilitate electroluminescence.

### EXAMPLES

The concepts described herein will be further described in the following examples, which do not limit the scope of the invention described in the claims.

### Examples 1-3 and Comparative A

These examples illustrate the performance of OLED devices in which the photoactive layer is vapor deposited. The hole injection layer was formed by spin-coating. All other layers were formed by vapor deposition. The devices had the layers with the materials listed below:
anode=Indium Tin Oxide (ITO) (50 nm)
hole injection layer=HIJ-1 (50 nm), which is made from an aqueous dispersion of an electrically conductive polymer and a polymeric fluorinated sulfonic acid. Such materials have been described in, for example, published U.S. patent applications US 2004/0102577, US 2004/0127637, and US 2005/0205860.
hole transport layer=HT-1 (20 nm), which is an arylamine-containing copolymer. Such materials have been described in, for example, published U.S. patent application US 2008/0071049.
photoactive layer=13:1 host H1:dopant E1 (32 nm). Host H1 is an anthracene derivative. Such materials have been described in, for example, U.S. Pat. No. 7,023,013. E1 is a blue-emissive arylamine compound. Such materials have been described in, for example, U.S. published patent application US 2006/0033421.
electron transport layer=2,4,7,9-tetraphenyl-1,10-phenanthroline (10 nm)
electron tunneling layer=CsF, with the thickness given in Table 1 cathode=Al (100 nm)
   The device properties are given in Table 1.

TABLE 1
Device Properties

| | CsF | | | | | T50 |
|---|---|---|---|---|---|---|
| Example | (Å) | EQE % | V (volts) | CIEx | CIEy | (hours) |
| Comp. A | 7 | 8.6 | 3.3 | 0.139 | 0.109 | 2369 |
| Ex. 1 | 15 | 8.4 | 3.5 | 0.139 | 0.109 | 3799 |
| Ex. 2 | 25 | 7.1 | 4.2 | 0.139 | 0.109 | 5637 |
| Ex. 3 | 35 | 7.1 | 4.5 | 0.138 | 0.111 | 5821 |

EQE = external quantum efficiency at 1000 nits; V = voltage at 300 A/m²; CIEx and CIEy are the x and y color coordinates according to the C.I.E. chromaticity scale (Commission Internationale de L'Eclairage, 1931); T50 is the time in hours to reach 50% of initial luminance at 1000 nits.

### Examples 4-6 and Comparative B

These examples illustrate the performance of OLED devices in which the photoactive layer is formed by liquid deposition. The hole injection layer, hole transport layer, and photoactive layer were formed by spin-coating. All other layers were formed by vapor deposition. The devices had the layers with the materials listed below:
anode=ITO (50 nm)
hole injection layer=HIJ-1 (50 nm)
hole transport layer=HT-1 (20 nm)
photoactive layer=13:1 host H1:dopant E2 (40 nm). E2 is a blue-emissive arylamine compound. Such materials have been described in, for example, U.S. published patent application US 2006/0033421.
electron transport layer=2,4,7,9-tetraphenyl-1,10-phenanthroline (10 nm)
electron tunneling layer=CsF, with the thickness given in Table 2 cathode=Al (100 nm)
   The device properties are given in Table 2.

TABLE 2
Device Properties

| | CsF | | | | | T50 |
|---|---|---|---|---|---|---|
| Example | (Å) | EQE % | V (volts) | CIEx | CIEy | (hours) |
| Comp. B | 7 | 5.9 | 3.7 | 0.135 | 0.139 | 6755 |
| Ex. 4 | 14 | 6.0 | 4.0 | 0.135 | 0.133 | 9559 |
| Ex. 5 | 24 | 5.3 | 4.5 | 0.134 | 0.135 | 15,515 |
| Ex. 6 | 35 | 4.8 | 4.8 | 0.134 | 0.140 | 11,384 |

EQE = external quantum efficiency at 1000 nits; V = voltage at 300 A/m²; CIEx and CIEy are the x and y color coordinates according to the C.I.E. chromaticity scale (Commission Internationale de L'Eclairage, 1931); T50 is the time in hours to reach 50% of initial luminance at 1000 nits.

### Examples 7-8 and Comparative C

These examples illustrate the performance of OLED devices in which the photoactive layer is formed by liquid deposition. The procedure of Examples 4-6 was repeated, except that a green-emissive material, E3, was used. Such materials have been described in, for example, U.S. published patent application US 2006/0033421. The CsF layer thickness and device results are given in Table 3.

TABLE 3
Device Properties

| | CsF | | | | | T50 |
|---|---|---|---|---|---|---|
| Example | (Å) | EQE % | V (volts) | CIEx | CIEy | (hours) |
| Comp. C | 7 | 8.5 | 4.4 | 0.237 | 0.643 | 199,392 |
| Ex. 7 | 14 | 8.0 | 4.6 | 0.240 | 0.644 | 231,885 |
| Ex. 8 | 21 | 6.9 | 4.9 | 0.244 | 0.644 | 240,570 |

EQE = external quantum efficiency at 1000 nits; V = voltage at 300 A/m²; CIEx and CIEy are the x and y color coordinates according to the C.I.E. chromaticity scale (Commission Internationale de L'Eclairage, 1931); T50 is the time in hours to reach 50% of initial luminance at 1000 nits.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. An organic electronic device comprising:
an anode;
a photoactive layer;
an electron transport layer;
an electron tunneling layer having a thickness in the range of 10-50 Å; and
a cathode.

2. The device of claim 1, wherein the electron tunneling layer has a thickness in the range of 14-35 Å.

3. The device of claim 1, wherein the electron tunneling layer has a thickness in the range of 20-30 Å.

4. The device of claim 1, wherein the electron tunneling layer comprises a material selected from the group consisting of LiF, Li₂O, Li-containing organometallic compounds, Cs-containing organometallic compounds, CsF, Cs₂O, Cs₂CO₃ and combinations thereof.

5. The device of claim 1, wherein the electron tunneling layer consists essentially of a material selected from the group consisting of LiF, Li₂O, Cs-containing organometallic compounds, CsF, Cs₂O, Cs₂CO₃ and combinations thereof.

6. The device of claim 1, wherein the electron tunneling layer consists essentially of a material selected from the group consisting of LiF and CsF.

7. The device of claim 1, further comprising a hole injection layer between the anode and the photoactive layer.

8. The device of claim 1, further comprising a hole transport layer between the anode and the photoactive layer.

9. The device of claim 1, comprising
an anode;
a hole injection layer;
a hole transport layer;
an emissive layer;
an electron transport layer;
an electron tunneling layer having a thickness in the range of 10-50 Å; and
a cathode.

10. The device of claim 9, wherein the electron tunneling layer has a thickness in the range of 14-35 Å.

11. The device of claim 9, wherein the electron tunneling layer has a thickness in the range of 20-30 Å.

12. The device of claim 9, wherein the electron tunneling layer comprises a material selected from the group consisting of LiF, Li₂O, Li-containing organometallic compounds, Cs-containing organometallic compounds, CsF, Cs₂O, Cs₂CO₃ and combinations thereof.

13. The device of claim 9, wherein the electron tunneling layer comprises a material selected from the group consisting of LiF, Li₂O, Cs-containing organometallic compounds, CsF, Cs₂O, Cs₂CO₃ and combinations thereof.

14. The device of claim 9, wherein the electron tunneling layer comprises a material selected from the group consisting of LiF and CsF.

15. An organic electronic device consisting essentially of
an anode;
a hole injection layer;
a hole transport layer;
an emissive layer;
an electron transport layer;
an electron tunneling layer having a thickness in the range of 10-50 Å; and
a cathode.
